(19) United States
(12) Patent Application Publication
(10) Pub. No.: US 2015/0318054 A1
(43) Pub. Date: Nov. 5, 2015

(54) Data Operation in Shift Register Ring

(71) Applicant: HEWLETT-PACKARD DEVELOPMENT COMPANY, L.P., Houston, TX (US)

(72) Inventor: Ted A. Hadley, Sunnyvale, CA (US)

(21) Appl. No.: 14/650,631

(22) PCT Filed: Dec. 11, 2012
(86) PCT No.: PCT/US12/68992

§ 371 Date: Jun. 9, 2015

(51) Int. Cl. G11C 19/28

(52) U.S. Cl. CPC G11C 19/287

(57) ABSTRACT

A shift register ring stores bits. A data operation may be performed in the shift register ring if bits in the shift register ring are in a home position

### BACKGROUND

Memories are used within computing devices to store data. For example, data is stored and accessed within computing devices such as personal computers, notebook and laptop computers, smartphones, personal digital assistants (“PDAs”), tablet and slate devices, personal entertainment devices such as MP3 players and media players, set-top boxes, gaming consoles, appliances, embedded devices, smart meters, and other computing devices at memories such as random-access memories (“RAMs”).

Typically, data stored in RAM or other memory of a computing device is accessed by a processor and some operation is performed by the processor based on the data. For example, an encryption key can be stored at a memory and a processor can access the encryption key to encrypt or decrypt a document.

### BRIEF DESCRIPTION OF DRAWINGS

The embodiments are described in detail with reference to the examples shown in the following figures:

FIG. 1 illustrates a computing device;

FIG. 2 illustrates a memory control module;

FIG. 3 illustrates a table showing shifting of bits to different positions;

FIG. 4 illustrates memory cells comprised of flip-flops;

FIG. 5 illustrates a circuit to control inputs for a flip-flop;

FIG. 6 illustrates a truth table for the circuit shown in FIG. 5;

FIG. 7 illustrates a position indicator circuit connected to shift registers and clock select and clock enable circuits;

FIG. 8 illustrates a circuit for the memory control module used for a write data operation;

FIG. 9 illustrates a timing diagram for the write data operation;

FIG. 10 illustrates a circuit for the memory control module used for a read data operation;

FIG. 11 illustrates a timing diagram for the read data operation;

FIG. 12 illustrates a control logic circuit; and

FIG. 13 illustrates a method.

### DETAILED DESCRIPTION OF EMBODIMENTS

For simplicity and illustrative purposes, the principles of the embodiments are described by referring mainly to examples thereof. In the following description, numerous specific details are set forth in order to provide a thorough understanding of the embodiments. It is apparent that the embodiments may be practiced without limitation to all the specific details. Also, the embodiments may be used together in various combinations.

Sometimes data stored in memory does not change for literally years of operation. For example, an encryption key may be stored in the same memory locations over an extended period of time and is read many times but is never deleted or changed. When data is stored in the same memory locations over a long period of time, memory imprinting may occur due to various properties of the memory. For example, typically, memory is comprised of a semiconductor device that stores information (or data values) based on a state (e.g., a charge value, resistance value, or some other state) of the memory cells, within the memory. Due to various properties of the memory such as manufacturing processes, types and amounts of dopants, temperature, composition, or other properties, storage of data (or data values) in the same memory locations over an extended period of time can alter the physical characteristics of the memory such that the data becomes imprinted in the memory cells. As a result of this memory imprinting, the data stored in the memory cells can be determined or read even after being deleted or over-written or after volatile memory has been powered down. In other words, the memory can be susceptible to imprinting of the data. If the memory is in a computing device that was discarded after the data was deleted from the memory, an unauthorized user may still access the data from the computing device if the data was imprinted.

According to an embodiment, data values of a data set stored at various memory cells of a memory are periodically moved to other memory cells of that memory. The periodic movement of the data minimizes the possibility of memory imprinting for example by preventing the prolonged exposure of memory cells to a particular data value.

A memory for storing the data may include a bit-oriented architecture. For example, the memory may include a shift register ring comprised of a storage array of single-bit flip-flops, each to store a single bit of data. When shifting words of data through memory, the quality of the non-imprinting is related to the Hamming distance amongst all of the values. For example, if a logic 1 exists in the same position of most of the words of data, that location suffers reduced non-imprinting effectiveness if data is moved byte-by-byte to different memory locations. The shift register ring, however, may shift all the bits sequentially through the storage array and each bit carries equal effectiveness for non-imprinting, as opposed to shifting entire words byte-by-byte to different memory locations which may suffer from reduced non-imprinting effectiveness.

A microprocessor can access the memory comprised of a shift register ring through a data operation control circuit. A latch may be used to access the memory and may use two clocks to manage the shifting of data in the memory. Under quiescent conditions, a slow clock, e.g., 0.01-1.0 Hz, may be used to shift the data in the memory. A fast clock may be used to align data for data operations, such as read or write, between the memory and the microprocessor. The fast clock, which may be as fast as the circuit can handle, is used to align data to minimize wait time of the microprocessor so the data operation can be performed. In this way, both low power, but slow data shifting in the memory to avoid memory imprinting can coexist with fast, but higher power requirements, for aligning data to perform data operations.

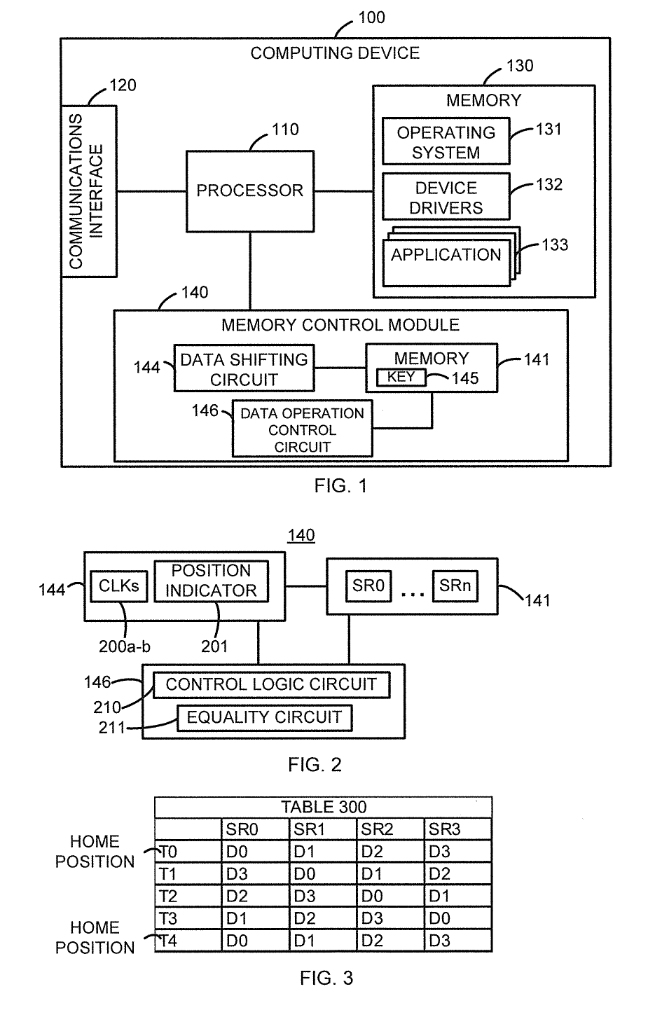

FIG. 1 illustrates a computing device 100 that includes a memory control module 140 with a memory 141. The memory 141 may include a physical device, such as semiconductor memory, comprised of memory cells to store data. In one example, the memory cells comprise shift registers as further described below. The computing device 100 also includes processor 110, communication interface 120, and storage device 130. The processor 110 is any of a variety of processors. For example, the processor 110 can be a general-purpose processor or an application-specific processor implemented as a hardware module and/or a software module hosted at a hardware module. A hardware module can be, for example, a microprocessor, a microcontroller, an application-specific integrated circuit (“ASIC”), a programmable logic device (“PLD”) such as a field programmable gate array (“FPGA”), and/or other electronic circuits that perform operations. A software module can be, for example, instructions, commands, and/or codes stored at a memory and executed at another processor. Such a software module can be defined using one or more programming languages such as Java™, C++, C, an assembly language, a hardware description language, and/or another suitable programming language. For example, a processor can be a virtual machine hosted at a computer server including a microprocessor and a memory.

In some implementations, the processor 110 can include multiple processors. For example, the processor 110 can be a microprocessor including multiple processing engines (e.g., computation, algorithmic or thread cores). As another example, the processor 110 can be a computing device including multiple processors with a shared clock, memory bus, input/output bus, and/or other shared resources. Furthermore, the processor 110 can be a distributed processor. For example, the processor 110 can include multiple computing devices, each including a processor, in communication one with another via a communications link such as a computer network.

The processor 110 is operatively coupled to the communications interface 120, the storage device 130, and the memory control module 140. The storage device 130 may store machine readable instructions or codes (e.g., computer codes or object codes) defining software modules that are executed by the processor 110 during operation of computing device 100. For example, the storage device 130 includes instructions that define operating system 131, device drivers 132, and applications 133 (e.g., software application programs). In other words, the operating system 131, the device drivers 132, the applications 133, and other software modules stored as instructions (not shown) at the storage device 130 and executed at the processor 110 are hosted at the computing device 100. The applications 133 can include, for example, an application software module, a hypervisor, a virtual machine module, or an environment such as a runtime environment or virtual machine instance. As a specific example, the applications 133 can include a cryptographic service such as a file encryption application.

The storage device 130 may include volatile memory and/or non-volatile (or non-transient) memory or processor-readable medium (not shown) such as a hard disk drive (“HDD”), a solid-state drive (“SSD”), a FLASH drive, or is in communication with a data storage service (e.g., via communications interface 120 and a communications link such as a communications network) at which software applications (e.g., computer codes or instructions that implement software applications when executed at a processor), data, or combinations thereof can be stored and accessed by the processor 110. Such software applications, data, or combinations thereof can be moved or copied to the storage device 130 by the processor 110 and accessed by the processor 110 at the storage device 130 during operation of the computing device 100.

Examples of processor-readable media include, but are not limited to: magnetic storage media such as a hard disk, a floppy disk, and/or magnetic tape; optical storage media such as a compact disc (“CD”), a digital video disc (“DVDs”), a compact disc read-only memory (“CD-ROM”), and/or a holographic device; magneto-optical storage media; non-volatile memory such as read-only memory (“ROM”), programmable read-only memory (“PROM”), erasable programmable read-only memory (“EPROM”), electronically erasable read-only memory (“EEPROM”), and/or FLASH memory; and random-access memory (“RAM”). Examples of computer code include, but are not limited to, micro-code or micro-instructions, machine instructions, such as produced by a compiler, and files containing higher-level instructions that are executed by a computer using an interpreter. For example, an implementation may be implemented using Java™, C++, or other object-oriented programming language and development tools. Additional examples of computer code include, but are not limited to, control signals, encrypted code, and compressed code.

The communications interface 120 is comprised of one or more interfaces accessible to the processor 110 to communicate with (i.e., transmit symbols representing data to and receive such symbols from) other processors or computing devices via a communications link. In other words, the communications interface 120 can receive data from the processor 110 and transmit symbols representing the data via a communications link. Moreover, the communications interface 120 can receive symbols from other communications interfaces via a communications link and send data represented by those symbols to processor 110. For example, the communications interface 120 can be a telephone network interface, a twisted-pair network interface, a coaxial network interface, a fiber-optic network interface, a wireless network interface such as a wireless local area network (“WLAN”) or a cellular network, a universal serial bus and/or some other network or communications interface.

The memory control module 140 includes data shifting circuit 144, memory 141 and a data operation control circuit 146. An encryption key 145 is shown as stored in the memory 141 as an example of data that may be stored in the memory 141. However, any data may be stored in the memory 141. The data shifting circuit 144 includes circuitry to prevent memory imprinting at the memory 141. The data shifting circuit 144 periodically moves the key 145 (i.e., bits of key 145) within the memory 141 to prevent memory imprinting of the key 145 in the memory 141. The data operation control circuit 146 facilitates data operations between the processor 110 and the memory 141. The data operation control circuit 146 aligns data for reading or writing. Also, the data operation control circuit 146 enables and disables a fast and slow clock to perform data operations.

The memory control module 140 may be provided on the same integrated circuit as the processor 110 or the memory control module 140 may be provided on a separate integrated circuit. The memory control module 140 may be part of the computing device 100 or may be on a separate device which may be connected to the computing device 100 via the communications interface 120, such as a universal serial bus port, a network interface, etc. Also, the memory 141 may also be referred to a memory circuit. For example, the memory 141 is comprised of semiconductor devices on an integrated circuit.

FIG. 2 shows the memory 141 comprised of shift registers SR0-SRn where n is an integer greater than or equal to 1. A shift register may include a single-bit register that stores a single bit and is an example of a memory cell. The shift registers may be connected as a shift-register ring where the output of one is connected to the input of another so each bit can be periodically shifted from one shift register to the other.

The data shifting circuit 144 may include clocks 200a-b and a position indicator 201. For example, the clock 200a is a fast clock and the clock 200b is a slow clock. The fast clock 200a may be faster than the processor clock and the slow clock 200b may be multiple orders slower than the fast clock 200a. In another example, one clock may be used and the clock frequency is changed to provide a fast and slow clock. The position indicator 201 indicates the positions of bits in the shift registers as the bits are periodically shifted. In one example, the position indicator 201 comprises a counter as is further described below.

The shifting may be performed on a clock pulse generated by one or more of the clocks 200a-b, and an example of the shifting is represented in table 300 shown in FIG. 3. For example, data stored in the shift registers of the memory 141 is shifted by the slow clock 200b to avoid imprinting. However, when a data operation is to be performed, the fast clock 200a is used to shift the data to a home position to minimize the wait time for the processor 110 so the data operation can be performed. For example, data stored in the shift registers in the shift-register ring is comprised of bits D0-D3 and assume the bits are written to the memory 141 and are in a home position at a time T0. The home position may be the locations of a set of bits (which may be word of predetermined length) after they are all written to the memory 141 but before the bits are shifted. For example, the home position is when bits D0-D3 are stored in the shift registers SR0-SRn respectively. At a first clock pulse after T0, shown as T1, the bits are shifted by one bit to the right. Thus at T1, D0 is shifted into SR1; D1 is shifted into SR2; D2 is shifted into SR3; and D3 is shifted into SR0. At a second clock pulse at T2, the bits are shifted again. Thus, at T2, D0 is shifted into SR2; D1 is shifted into SR3; D2 is shifted into SR0; and D3 is shifted into SR1. At a third clock pulse at T3, the bits are shifted again. Thus, at T3, D0 is shifted into SR3; D1 is shifted into SR0; D2 is shifted into SR1; and D3 is shifted into SR2. At T4, the bits are shifted back to the home position. The shifting described above may be performed according to the slow clock 200b unless a signal is received that a data operation is to be performed and then the shifting is performed according to the fast clock 200a.

FIG. 2 also shows that the data operation control circuit 146 may be comprised of a control logic circuit 210 and an equality circuit 211. The control logic circuit enables the slow clock 200b or the fast clock 200a to control the shifting of bits in the shift registers SR0-SRn. Also, the control logic circuit 210 may disable the clock 200a and 200b to perform a data operation for the processor 110, such as a read or a write in the shift registers SR0-SRn. The control logic circuit 210 also generates a read or write enable signal to control the reading and writing in the shift registers SR0-SRn.

The equality circuit 211 determines whether data in the shift registers SR0-SRn is in a home position so the data operation can be performed. For example, the home position is a home position of a specific word in the shift registers being addressed, and the equality circuit 211 determines whether the word is in its home position. For example, the memory control module 140 receives an address, such as a read address or a write address, from the processor 110 for the data operation. The equality circuit 211 compares bits from the address (e.g., some of the least significant bits of the address that identify a word to be written or read) to bits from the position indicator 201 (e.g., some of the most significant bits) that identify a position of a word in the shift registers SR0-SRn. Some of the least significant bits of the address may include at least two bits but not all the bits of the address, and some of the most significant bits from the position indicator 201 may include at least two bits but not all bits output from the position indicator 201. If the value of the bits from the address and the position indicator 201 match, then the word in the shift registers SR0-SRn is in the home position and the data can be written into the shift registers SR0-SRn at one time or read from the shift registers SR0-SRn at one time. The operation of the circuits is described in further detail below.

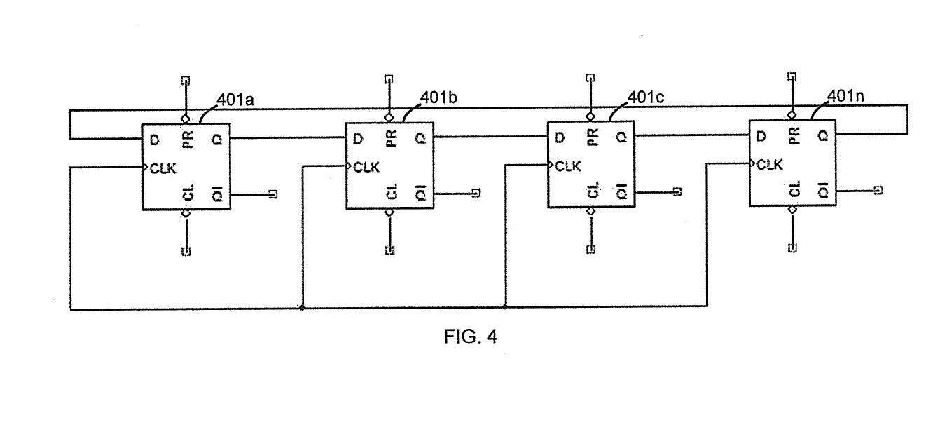

FIG. 4 illustrates an example of the shift registers in the memory 141. The shift registers may include an array of D flip-flops 401a-401n sharing the same clock and connected to form a shift register ring. Each flip-flop has a Q data output connected to a D input of another flip-flop. The Q output of the flip-flop is the data output for each bit position.

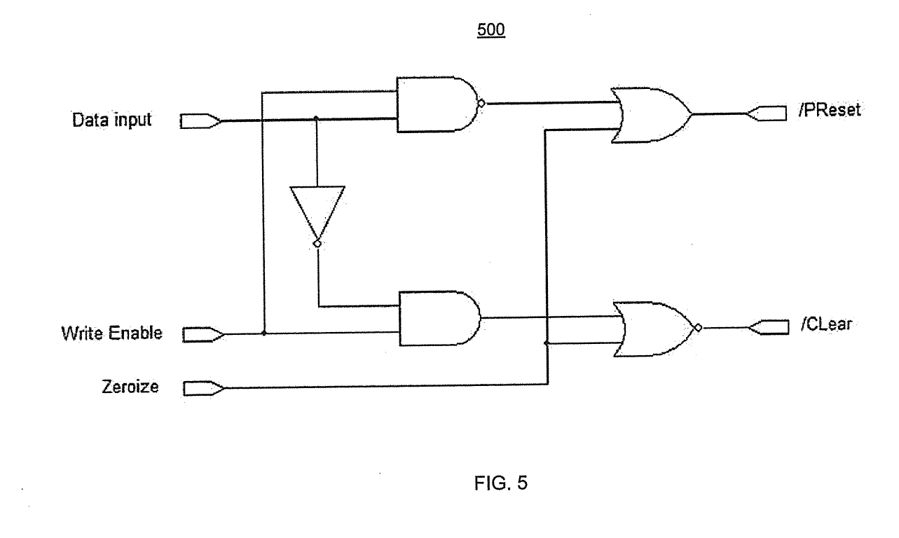

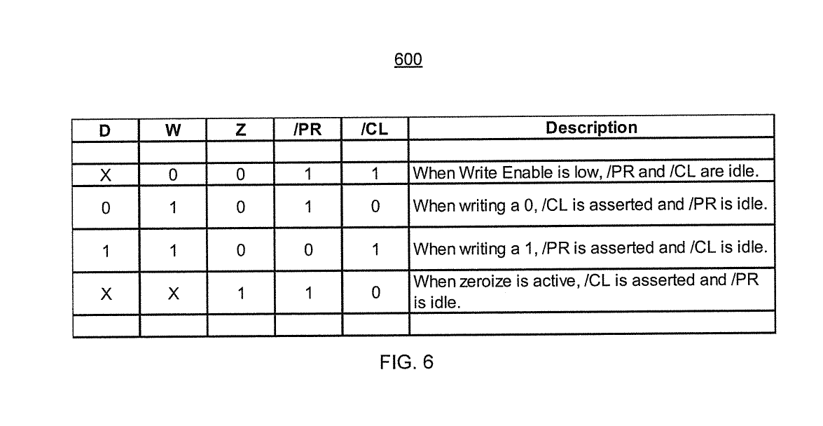

Each flip-flop has PReset an CLear inputs, and these inputs may be active low. FIG. 5 shows an example of a circuit 500 for controlling the PR and CL inputs and the writing of data to a flip-flop. The circuit 500 may be included in the memory control module 140 shown in FIG. 1. To write a ‘1’ bit to the D flip-flop, the PR is set to 0 (e.g., active low) and the CL is set to 1 (e.g., also active low). Following a write cycle, both PR and CL are set to 1 (the idle state). Writing a 0 is the same except PR is set to 1 and CL is set to 0. Also, a zeroize operation may be performed to reset the flip-flop data to 0 and the zeroize input may be connected to all flip-flops at once to reset all the flip-flops to 0 simultaneously. FIG. 6 shows a table 600 that is the truth table for controlling PR and CL and write operations which reiterates the description above for FIG. 5.

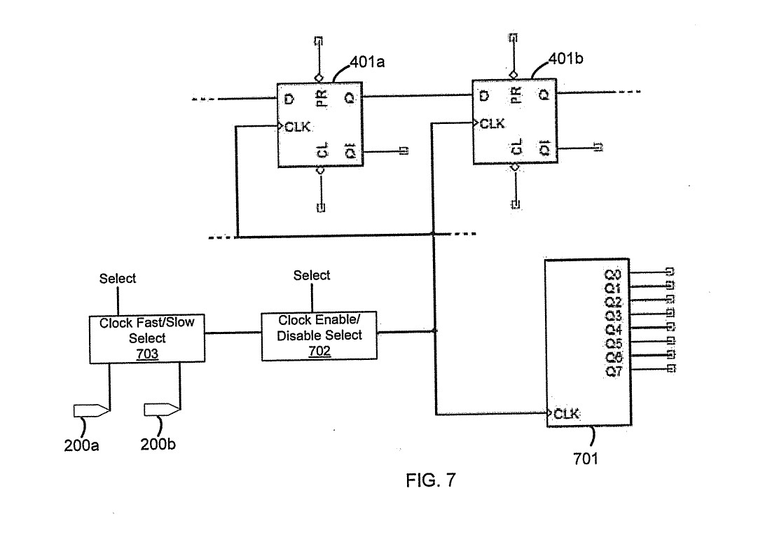

FIG. 7 shows the clocks 200a-b and a counter 701 that may operate as the position indicator 201 from FIG. 2. The counter 701 keeps track of the actual data position of the bits in the shift registers, such as the data positions shown in FIG. 3. For example, a counter value 0 means the bits are in the home position; after a shift, the counter 701 is incremented and the counter value 1 means the bits are in a position associated with T1 shown in FIG. 3, and so on. The number of bits in the shift registers should be of count 2^{x}, where x is the number of bits in the counter 701. A clock select circuit 703 may be used to select the slow or fast clock, and a clock disable circuit 702 may be used to enable or disable the clocks 200a-b. Select signals may be provided to the circuits 702 and 703 from the control logic circuit 210 to select the clock and the enable/disable.

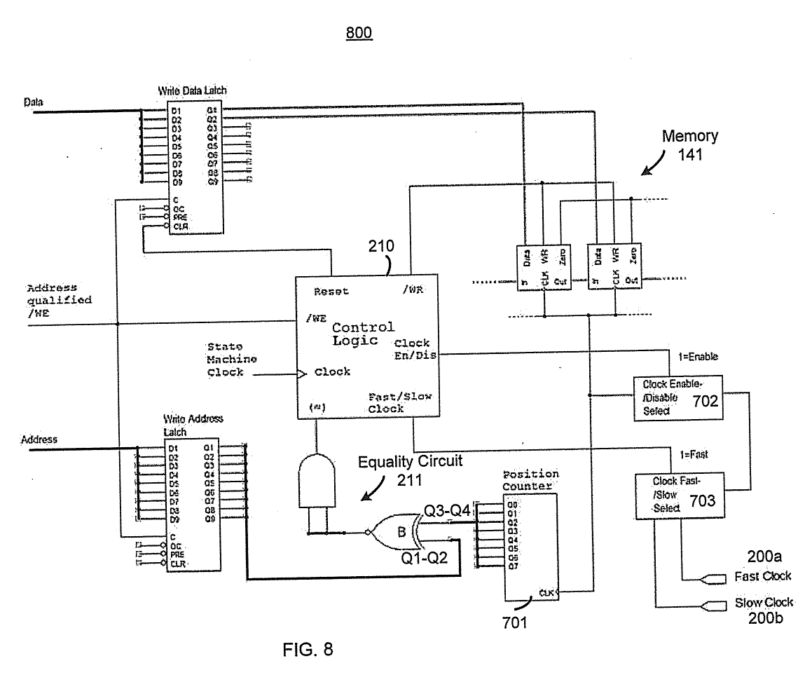

FIG. 8 shows an example of a circuit 800 for the memory control module 140 shown in FIG. 1. The data shifting circuit 144 of FIGS. 1-2 including the clocks 200a-b, and the position indicator 201 comprised of counter 701 are shown in FIG. 8. Also shown are the control logic circuit 210 and equality circuit 211. In this example, the equality circuit 211 is comprised of the AND and XNOR gates shown in FIG. 8 of the data operation control circuit 146. The clock select circuit 703 and the clock disable circuit 702 from FIG. 7 are also shown. A read data latch may be used to enable or disable the clocks 200a-b. Select signals may be provided to the circuits 702 and 703 from the control logic circuit 210 to select the clock and the enable/disable. The clock disable circuit 702 inhibits propagation of the clock signal generated by either of the clocks 200a-b to prevent shifting for example when a write is being performed. The clock select circuit 703 selects either the fast clock 200a (e.g., to shift bits in the shift registers to the home position for a data operation of the processor 110) or the slow clock 200b (e.g., to shift bits in the shift register if no data operation for the processor is being performed in the shift registers). The write data latch receives data from a system bus to be written to the shift registers. The write address latch receives an address from the processor 110 for writing the data.

The memory 141 shown in FIG. 1 may include memory cells comprised of shift registers as described above. FIG. 8 shows some of the shift registers. In one example, the shift registers in FIG. 8 are comprised of D flip-flops such as shown in FIG. 4. The number of shift registers may be at least as many as the number of bits that are to be stored in the memory 141 but there may be more shift registers than number of bits. The shift registers for example are connected as a shift register ring.

The control logic circuit 210 controls access to the shift registers to perform data operations, such as a read or write. All the data, for example, is read from the shift registers or written to the shift registers at one time, such as at a single clock pulse. The data may comprise any bit or group of bits (e.g., word). The word size may be the native word size of the processor 110.

The control logic circuit 210 determines whether bits in the shift register are in a home position based on information from the equality circuit 211 to control the clocks 200a-b and to enable data operations. The equality circuit 211 performs a comparison from position information from the position counter 701 to information from the write address received from the write address latch to determine whether bits in the shift register are in a home position to enable a data operation. Assume 32 bits are stored in the shift registers of the memory 141. For example, there are 32 single-bit shift registers in the shift register ring of the memory 141. The bits are grouped into words, for example, having the native word size used by the processor. For example, assume the native word size of the processor 110 is 8 bits (“byte-wide”), and the shift registers of the memory 141 store four 8-bit words. In this example, the position counter 701 uses 5 bits for its output to represent the position of the bits in the 32-bit shift register, so the position counter uses bits Q0-Q4 for its output.

When the processor 110 wishes to address different bytes (words), the low-order address bits (e.g., least significant bits) of the write address select the byte in the memory 141 for the write data operation. For example, output bits Q1 and Q2 of the write address latch select the bytes in the memory 141 for the write data operation. Also, the position counter 701 provides two values. The low-order bits (Q0-Q2) of the counter 701 establish the alignment of a group of 8 bits (a byte) within the shift registers, while the remaining upper bits (e.g., most significant bits Q3-Q4) select the correct one of a plurality of aligned words in the shift register. In the position counter 701, the number of low-order bits is log₂(bit width) bits. In this example, the bit width is 8 bits, so log₂8=3 bits. The 3 low-order bits of the position counter output are ignored. The remaining 2 upper-order bits (most significant bits) are used by the equality circuit 211 to compare to some of the address bits, and the remaining upper-order bits identify the word position in the shift registers. The same number of bits, which is 2 in this example, are used to identify the number of least significant bits in the address to compare to the most significant bits of the position counter output.

In this example, the equality circuit 211 compares the value of the upper-order bits (e.g., most significant bits Q3-Q4) of the position counter 701 with the value of the low-order bits (least significant bits Q1-Q2) of the write address latch to determine whether they are equal. When the values are equal, the XNOR outputs a “1” (e.g., logic level high) and the AND gate outputs a “1” to the “=” input in the control logic circuit 210, which means the position of bits in the shift registers is aligned with the home position for the word identified by the address latch (e.g., the words in the shift registers are in their home position and the data operation can be performed in the memory 141). When “=” is “1” the control logic circuit 210 enables the data operation. For example, the clocks 200a-b are disabled, and the /WR output is toggled to perform the write operation in the shift registers as described below.

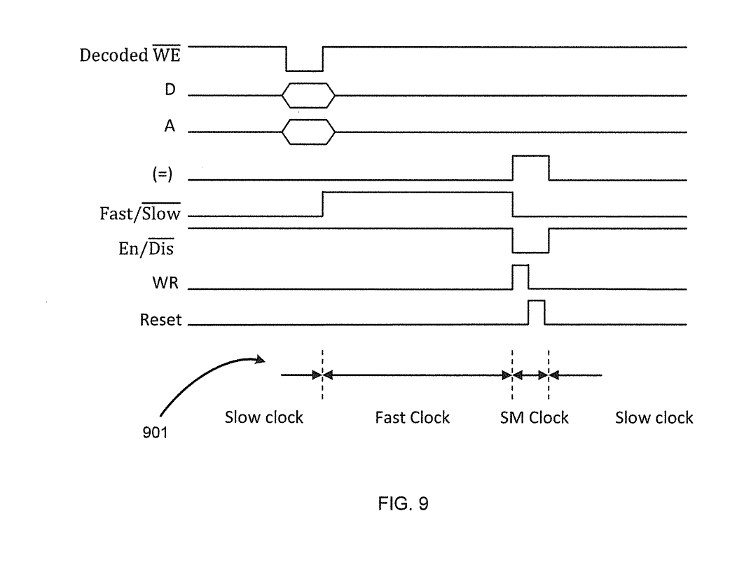

FIG. 9 shows a timing diagram of the write operation performed in the circuit 800. The processor 110 writes data to be stored in the shift register to the write data latch shown in FIG. 8, and the address where it is to be saved is written to the address latch. The /WE (Write Enable) signal from the processor 110 is used to latch the values. This /WE may not be the native /WE, but one that has already chip select qualified. In other words, the /WE is ORed with /ChipSelect to drive /WE. Since the data is latched, processor 110 involvement is now complete.

Under normal operating conditions, the bits in the shift registers in the memory 141 are rotating through the shift registers using the slow clock 200b. A slow clock may be used because a fast clock is not necessary, and a slow clock uses less power. After the /WE signal latches the write data and its address, when /WE is released, the shift register clock switches to the fast clock 200a. The fast clock 200a may be as fast as the devices in the circuit 800 can reliably operate. The response time of the circuit 800 to the processor 110 is related to the speed of the fast clock 200a.

When the counter output matches the address desired as indicated by the output of the equality circuit 211, the (=) signal is raised to “1” to indicate the data in the shift registers has moved to correct location for writing. When the (=) signal is “1”, the fast clock 200a is stopped. This freezes the position of the data in the shift registers momentarily. With the shift register data is stopped, the data from the write data latch is loaded into the shift registers. This is controlled by a state machine clock of the control logic circuit 210. This can be any relatively fast clock in the system, and the fast clock 200a may be used.

After the data is written to the shift registers, the state machine clock produces an additional clock pulse to the write data latch to clear its data to avoid imprinting in the write data latch. Finally, after the write data latch is erased, the shift register clock is restored to the slow clock 200b, and rotating of data in the shift register continues. A logical OR of the signals (=) and Fast/Slow may be performed to provide a “busy” signal. This busy signal may be monitored to indicate to the processor 110 whether the shift registers are busy (or /idle); if busy, the shift registers are currently loading or unloading data, but if idle, an access may be made. The bottom of FIG. 9, at 901, shows which clock is enabled at particular time periods in the timing diagram. First the slow clock 200b is enabled to shift the data in the shift registers, then the fast clock 200a is enabled to move the addressed word to its home position, and then clocks 200a-b are disabled and the state machine clock (SM) clock is enabled to write data to the shift registers and to reset the write data latch. Then, the slow clock 200b is enabled to shift the data in the shift registers.

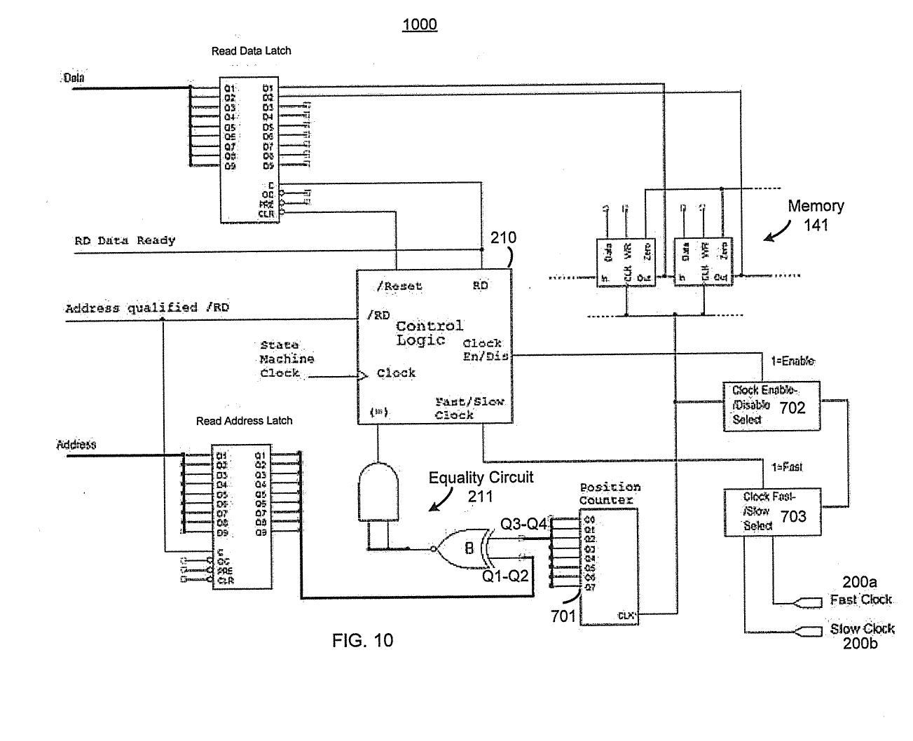

FIG. 10 shows the memory circuit 800 for a read operation instead of a write operation for the processor 110. The memory circuit 800 is the same as shown in FIG. 8 except the write data latch now operates as a read data latch to receive data from the shift registers for transmission on a system bus for use by the processor 110. Also, the write address latch now operates as a read address latch to receive an address for reading data from the shift registers. In another example, separate read and write latches may be used for the data and/or the address.

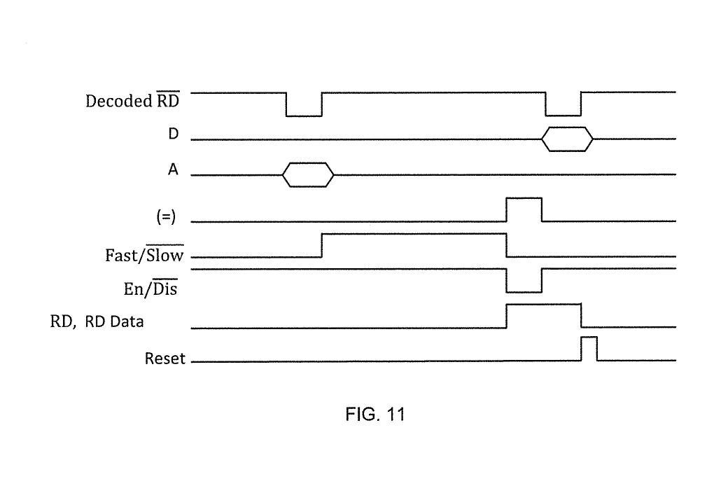

FIG. 11 shows a timing diagram of the write operation performed in the circuit 800. In the write operation, the write data input latch held the write data so the processor 110 did not have to finish the cycle. In one example, when reading data from the shift registers, the processor 110 performs two reads. The processor 110 first reads and discards the value (typically it will be all Os because that is the ending state from the previous operation). Then, when the data is in the read data latch, the processor 110 reads again. The operation with respect to the timing diagram shown in FIG. 10 is now described.

The processor 110 asserts /RD to read the value. /RD may be chip select qualified similar to NVE in the write cycle. Under normal operating conditions, the shift registers rotate bits using the slow clock 200b. After the /RD signal latches the read address, when /RD is released, the shift register clock switches to the fast clock 200a. When the most significant bits of the position counter match the least significant bits of the read address, the (=) signal is asserted to indicate the data in the shift registers has moved to correct location for reading. When the (=) signal is “1”, the fast clock 200a is stopped. This freezes the position of the data in the shift registers. So far the read operation is similar to the write operation but now it becomes different. The (=) signal drives the RD signal. The RD signal takes the (now static) data from the shift register and latches it into the read data latch. Since the latch is edge triggered, once the rising edge of the RD signal has passed, the input data to the read data latch can change without affecting the data stored in the latch. After the read data latch is clocked to store the read data, the clocking for the shift registers continues using the slow clock 200b. The RD signal is held high until the processor 110 reads the read data latch again. The RD signal is sent to the processor 110 as an indicator that data is ready to be read from the read data latch. After the processor 119 reads the read data latch again, upon receiving the data, the read data latch is reset. In this example, the state machine clock is not needed for the read operation.

In another example, the state machine clock may be used for the read operation. In this example, the RD Data Ready signal is asserted by the control logic circuit 210 to indicate to the processor 110 that the data is in the read data latch. The processor 110 is in a wait state until the RD Data Ready signal is asserted, and when asserted, the processor 110 can read the data from the read data latch. In this example, the state machine clock is used to reset the data latch on the second pulse similar to the write operation. Also, in this example, the processor 110 does not perform two reads but instead performs one read and goes into a wait state until the data is read from the read data latch.

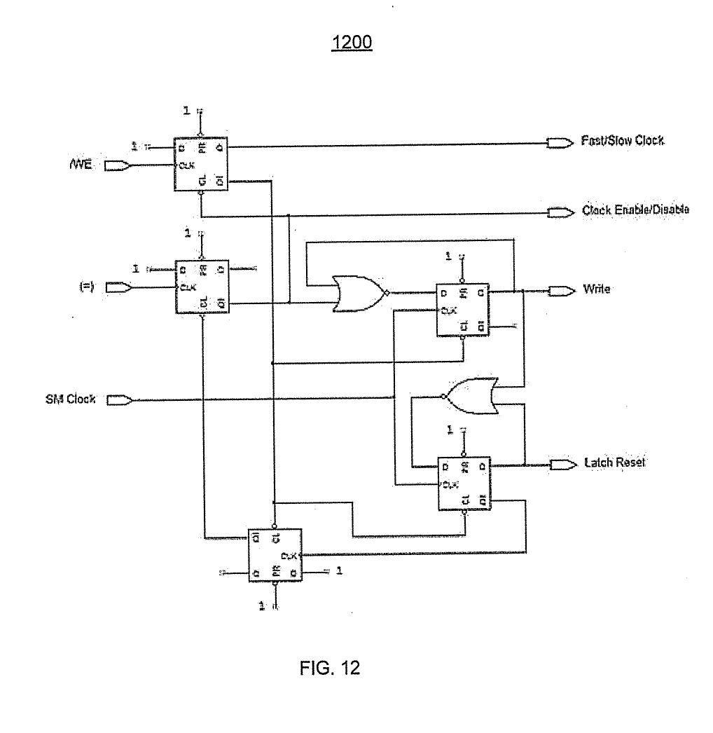

FIG. 12 shows one example of the logic that may be used for the control logic circuit 210. The control logic circuit 210 can be implemented in many ways and the circuit shown in FIG. 12 is one example of an implementation of control logic circuit 210.

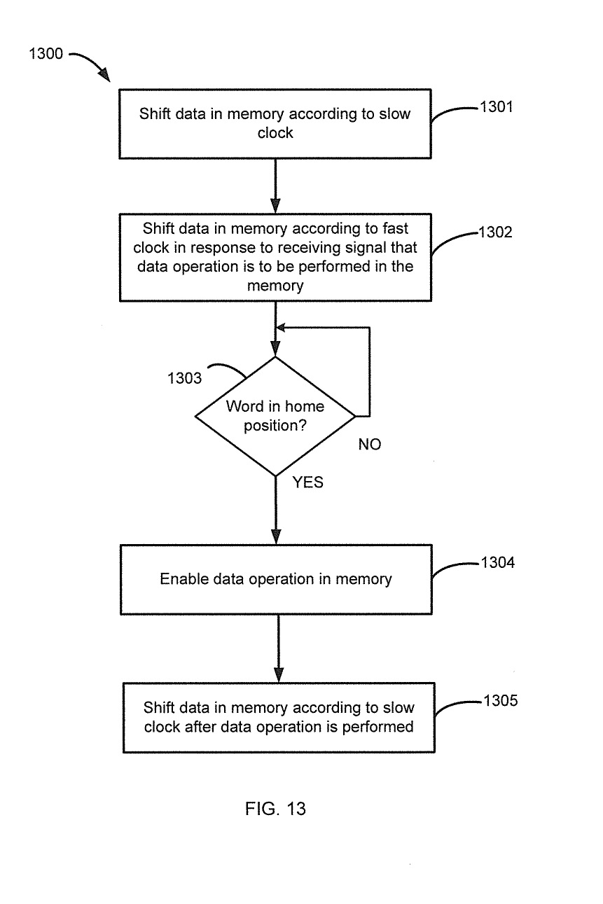

FIG. 13 illustrates a method 1300. The method 1300 may be performed by the memory control module 140 for example shown in FIGS. 1, 2, 8 and 10 and described above. At 1301, bits are shifted in a shift register ring of the memory 141 for each clock pulse generated by the slow clock 200b (e.g., under normal operating conditions). At 1302, the bits in the shifted in the memory 141 are shifted for each clock pulse generated by the fast clock 200a in response to receiving a signal at the control logic circuit 210 that the data operation is to be performed (e.g., /WE is asserted). At 1303, the equality circuit 211 determines whether a word in the shift register ring of the memory 141 is at a home position based on information from the position counter 701 (e.g., most significant bits) and some bits from an address (e.g., least significant bits) received from the processor 110 to perform a data operation in the shift register ring. If the word is in the home position, the data operation (e.g., read or write data at one time to or from memory 141) is enabled by the control logic circuit 210 at 1304 and, after the data operation is performed, at 1305, the data in the memory 141 is shifted according to the slow clock 200b. If the word is not at the home position as determined at 1003, the data is shifted according to the fast clock 200a until the equality circuit 211 determines the data is in the home position.

While the embodiments have been described with reference to examples, various modifications to the described embodiments may be made without departing from the scope of the claimed embodiments.

What is claimed is:

1. A memory circuit comprising:
a shift register ring including single-bit shift registers, wherein a clock is connected to the shift registers to shift bits within the shift register ring;
a shift register position indication circuit to indicate positions of the bits in the shift register ring; and
a data operation control circuit including
an equality circuit to determine whether a position of a word in the shift register ring is at a home position based on information from the shift register position indication circuit and bits from an address received from a processor to perform a data operation of the processor in the shift register ring, and
a control logic circuit to enable the data operation in the shift register ring if the word is determined to be in the home position, wherein the data operation includes reading bits from the shift register ring at one time or writing data to the shift register ring at one time.

2. The memory circuit of claim 1 wherein the control logic circuit is to disable the clock, and the data operation is enabled after disabling the clock, and
wherein the control logic circuit is to enable the clock after the data operation is performed.

3. The method of claim 2, wherein the clock comprises a fast clock and a slow clock and the control logic circuit is to enable the fast clock to shift the bits in the shift register ring to a home position in response to receiving a signal from the processor to perform the data operation, and
to disable the clock, the control logic circuit is to disable the fast clock to read or write data from the shift register ring, and
to enable the clock after the data operation is performed, the control logic circuit is to enable the slow clock after the data operation is performed.

4. The memory circuit of claim 1, wherein the shift register position indication circuit comprises a counter connected to the clock, and bits output from the counter indicate positions of words in the shift register ring.

5. The memory circuit of claim 4, wherein each shift register stores only a single bit of data and for each clock pulse generated by the clock, each bit in the shift register ring is shifted to a next shift register in the ring, and the counter is incremented by one unless the bits are in a final position, and then the counter is reset to 0.

6. The memory circuit of claim 4, wherein most significant bits of the counter output indicate position of each of a plurality of words in the shift register ring, wherein each word has a native word size used by the processor.

7. The memory circuit of claim 6, wherein the bits from an address received from the processor comprise least significant bits of the address from the processor indicating a word to write to or read from the shift register ring, and the equality circuit is to determine whether values of the most significant bits of the counter output and the least significant read address bits are equal to disable the clock.

8. The memory circuit of claim 1, comprising a latch to store data for the data operation, and the control logic circuit is to enable sending the data from the latch to shift register ring for a write data operation or to enable sending the data from the shift register ring to the latch for a read data operation if the word is determined to be in the home position.

9. The memory circuit of claim 8, the control logic circuit is to reset the latch after the data operation is completed.

10. The memory circuit of claim 8, wherein the latch is connected to an output of each shift register.

11. The memory circuit of claim 1, wherein each shift register includes a zeroize input and each shift register is to simultaneously receive a zeroize active signal to reset each bit stored in the shift registers simultaneously.

12. A circuit comprising:
a control logic circuit connected to a fast clock and a slow clock, wherein the fast clock and the slow clock are connected to single-bit shift registers in a shift register ring to shift bits stored in the shift register ring, and
the control logic circuit is to
enable the fast clock to shift the bits in the shift register ring to a home position in response to receiving a signal of a data operation to be performed for a processor in the shift register ring,
disable the fast and slow clock in response to the bits being in the home position, wherein the data operation is performed in response to the bits being in the home position, and
enable the slow clock to shift the bits stored in the shift register ring after the data operation is completed.

13. A method comprising:
determining whether a position of a word in a shift register ring is at a home position based on information from a shift register position indication circuit and bits from an address received from a processor to perform a data operation in the shift register ring; and
if the word is in the home position, performing the data operation in the shift register ring, wherein the data operation includes reading bits from the shift register ring at one time or writing data to the shift register ring at one time.

14. The method of claim 13, comprising:
prior to performing the data operation, shifting bits in the shift register ring for each clock pulse generated by a clock;
disabling the clock;
performing the data operation; and
enabling the clock.

15. The method of claim 14, wherein the clock comprises a fast clock and a slow clock and the method comprises:
wherein the shifting the bits includes shifting the bits to a home position using the fast clock in response to receiving a signal from the processor to invoke the data operation
the disabling the clock includes disabling the fast clock; and
the enabling the clock includes enabling the slow clock after performing the data operation to shift bits in the shift register ring.
